(19) United States
(12) Patent Application Publication
(10) Pub. No.: US 2026/0293076 A1
(43) Pub. Date: Sep. 24, 2026

(54) PRODUCTION MANAGEMENT DEVICE

(71) Applicant: FUJI CORPORATION, Chiryu (JP)

(72) Inventors: Anusuya NALLATHAMBI, Chiryu-shi (JP); Kenji SUGIYAMA, Anjo-shi (JP)

(73) Assignee: FUJI CORPORATION, Chiryu (JP)

(21) Appl. No.: 19/473,349

(22) PCT Filed: Apr. 17, 2023
(86) PCT No.: PCT/JP2023/015316

§ 371 Date: Oct. 7, 2025

(51) Int. Cl. H05K 13/08

(52) U.S. Cl. CPC H05K 13/084

(57) ABSTRACT

A production management device includes a storage section configured to store sorting information for sorting component accommodation members into multiple groups, the component accommodation members accommodating components and being replaceably set in a component supply device constituting a component mounter, and error information indicating an occurrence history of an error in a mounting operation of collecting the components from the component accommodation members and mounting the components on a board in the component mounter, in association with identification information of each of multiple component accommodation members, and an aggregation section configured to aggregate or statistically process the error information for each of the multiple groups for the component accommodation members used in a predetermined aggregation period.

### TECHNICAL FIELD

The present description relates to a production management device related to a component mounter that performs a mounting operation of picking up a component from a component accommodation member and mounting the component on a board.

### BACKGROUND ART

A technique for mass-producing board products by performing multiple-step production work on a board on which a circuit pattern is formed has become widespread. As a representative example of a board production work machine that performs the production work, there is a component mounter that executes a mounting operation of mounting a component on a board. In general, the component mounter supplies a component using a component supply device in which a component accommodation member is replaceably set, and performs a mounting operation using a component mounting tool. In this type of component mounter, an error that causes failure in the mounting operation occurs once in a while. The location of a cause of an error varies such as a device such as a component supply device or a component mounting tool, a component accommodation member, and mounting data used for a mounting operation. In order to maintain good productivity, it is important to estimate the location of a cause according to an error occurrence status and take an appropriate countermeasure. An example of a technique related to estimation of the location of a cause of an error occurring in a board production work machine such as a component mounter is disclosed in Patent Literature 1.

A mounting quality factor analysis method disclosed in Patent Literature 1 includes a step of registering an inspection result in a solder printing step, an inspection result in a component mounting step, an inspection result in a soldering step, and a repair result obtained by performing board repair in a quality database on a component-by-component basis, a step of acquiring an inspection result in each production step, a step of aggregating defect occurrence states on a component-by-component basis and performing statistical processing, and a step of analyzing a statistical processing result between production steps and specifying a defect occurrence factor step and a defect factor. According to this technique, it is possible to narrow down the defect occurrence factor step and to significantly reduce quality defects by investigating the defect factor.

### CITATION LIST

### Patent Literature

Patent Literature 1: JP-A-2005-286015

### BRIEF SUMMARY

### Technical Problem

The technique of Patent Literature 1 is preferable in that the defect occurrence factor step can be narrowed down by analyzing (comparing) statistical processing results between production steps. However, it is difficult to say that a method and a device for estimating the defect factor (the location of a cause of an error) are sufficiently disclosed. In other words, the technique of Patent Literature 1 does not disclose a specific method or device for estimating the location of a cause of an error in the mounting operation that may occur in the component mounter.

Here, when the location of the cause of the error of the mounting operation is the device, it is possible to suppress a decrease in productivity by taking countermeasures such as maintenance. In addition, when the location of the cause is the mounting data, it is possible to suppress a decrease in productivity by taking countermeasures such as reexamination and correction of data and review of application conditions. Meanwhile, when the location of the cause is the component accommodation member, it is generally difficult for the user of the component accommodation member to take effective countermeasures, and productivity tends to decrease. Therefore, it is necessary to take countermeasures against errors caused by the quality of the component accommodation member.

Therefore, an object of the present description is to provide a production management device capable of reflecting an error in a mounting operation of a component mounter, in particular, an error caused by quality of a component accommodation member in an effective countermeasure by performing more detailed aggregation or statistical processing of error information than the conventional art.

### Solution to Problem

The present description discloses a production management device including: a storage section configured to store sorting information for sorting component accommodation members into multiple groups, the component accommodation members accommodating components and being replaceably set in a component supply device constituting a component mounter, and error information indicating an occurrence history of an error in a mounting operation of collecting the components from the component accommodation members and mounting the components on a board in the component mounter, in association with identification information of each of multiple component accommodation members; and an aggregation section configured to aggregate or statistically process the error information for each of the multiple groups for the component accommodation members used in a predetermined aggregation period.

### Advantageous Effects

In the disclosed production management device, the storage section stores sorting information for grouping the multiple component accommodation members and error information indicating an occurrence history of an error in the mounting operation in association with each piece of identification information of the multiple component accommodation members. The aggregation section aggregates or statistically processes the error information for each group for the component accommodation member used in the predetermined aggregation period. As described above, unlike the conventional art in which it is determined whether the location of the cause is the component accommodation member, detailed aggregation or statistical processing for each group is performed for multiple component accommodation members, and thus it is possible to compare the occurrence status of an error between groups and reflect the comparison result in an effective countermeasure.

### BRIEF DESCRIPTION OF DRAWINGS

FIG. 1 is a perspective view schematically illustrating an overall configuration of a component mounter to which a production management device of an embodiment is applied.

FIG. 2 is a functional block diagram illustrating the production management device according to the embodiment.

FIG. 3 is a diagram conceptually illustrating machine log data of the component mounter.

FIG. 4 is a diagram illustrating determination data representing a result of determination processing of a determination section.

FIG. 5 is a diagram of a processing flow illustrating a method of storage processing of a storage section.

FIG. 6 is a diagram illustrating reel data stored in the storage section.

FIG. 7 is a diagram of a processing flow illustrating a method of aggregation processing of an aggregation section.

FIG. 8 is a diagram illustrating an aggregation result of the aggregation section.

FIG. 9 is a diagram in which a display section displays the aggregation result illustrated in FIG. 8 as a graph, and is a diagram of the aggregation result for each vendor of a component.

FIG. 10 is a diagram in which the display section displays a second aggregation result in a graph, and is a diagram of the aggregation result for each vendor of the component.

FIG. 11 is a diagram in which the display section displays, in a graph, a third aggregation result aggregated by the aggregation section for each type of the component for a vendor A in FIG. 10.

FIG. 12 is a diagram of another graph displayed by the display section and is a diagram illustrating another aggregation method of the aggregation section.

FIG. 13 is a diagram of yet another graph displayed by the display section, and is a diagram illustrating yet another aggregation method of the aggregation section.

### DESCRIPTION OF EMBODIMENTS

### 1. Configuration Example of Component Mounter 1

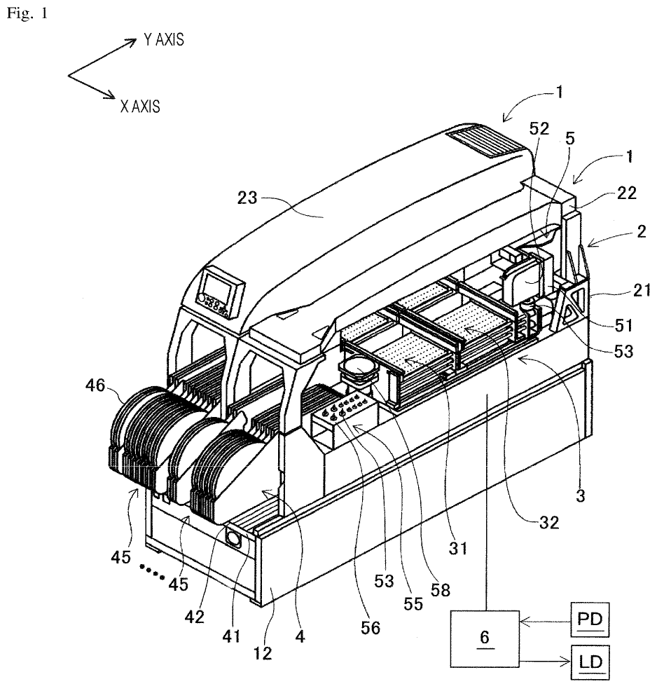

First, a configuration example of component mounter 1 to which production management device 7 of an embodiment is applied will be described with reference to FIG. 1. In FIG. 1, two component mounters 1 are disposed adjacent to each other on system base 12. The direction in which component mounters 1 are arranged coincides with an X-axis direction for conveying a board, and the horizontal direction orthogonal to the X-axis direction is a Y-axis direction. Each component mounter 1 includes mounter housing 2, board conveyance device 3, component supply unit 4, head moving device 5, mounting head 52, nozzle station 55, part camera 58, a control device 6, and the like. Mounter housing 2 includes frame portion 21, beam portion 22 bridged above frame portion 21, and an openable and closable protection cover 23 provided above beam portion 22.

Board conveyance device 3 includes two sets of conveyor mechanisms 31 and 32 and board holding mechanisms (not illustrated). Two conveyor mechanisms 31 and 32 are disposed on the upper surface of frame portion 21 so as to be parallel to each other and extend in the X-axis direction. Each of conveyor mechanisms 31 and 32 is rotationally driven by a motor (not illustrated) to convey a board to be supported in the X-axis direction. Two board holding mechanisms are disposed substantially at a lower portion of the center of each of conveyor mechanisms 31 and 32. Each of the board holding mechanisms holds a board at a predetermined mounting operation position. Board conveyance device 3 may include only one set of conveyor mechanisms.

Component supply unit 4 includes pallet table 41 and multiple tape feeders 45. Pallet table 41 is disposed on the upper surface of frame portion 21. Pallet table 41 has multiple slots 42 extending parallel to each other in the Y-axis direction. Position ID information for position identification is assigned to each of multiple slots 42. For example, when the total number of slots 42 is 24, the position ID information of S01 to S24 is assigned.

Tape feeder 45 is one form of a component supply device constituting component mounter 1. Each of tape feeders 45 is inserted into slot 42. Each of tape feeders 45 rotatably supports set reel 46. Carrier tape is wound around reel 46. The carrier tape includes a base tape in which components are respectively accommodated in multiple cavities arranged in a row, and a cover tape that is peelably bonded to the base tape and covers the cavities. The combination of the carrier tape and reel 46 is one form of a component accommodation member. In the following description, “reel 46” is used as a term including a wound carrier tape.

Tape feeder 45 rotationally drives a sprocket engaged with a feed hole provided in the carrier tape, feeds the carrier tape to a predetermined component supply position by pitch feeding, and peels off the cover tape. As a result, tape feeder 45 supplies the component at the component supply position. Device ID information for individual identification is assigned to each of tape feeders 45. Tape feeder 45 may have a separate type configuration in which a reel holding device that holds reel 46 is provided separately. Component supply unit 4 may include a tray feeder as the component supply device. The tray feeder uses a tray in which components are respectively accommodated in multiple accommodation portions arranged in a lattice shape as a component accommodation member.

Head moving device 5 is an XY robot type device and is disposed on the lower surface of beam portion 22. Head moving device 5 slides slider 51 in two horizontal directions by an X-axis motor and a Y-axis motor (not illustrated). Mounting head 52 is provided on a side surface of slider 51. Mounting head 52 moves integrally with slider 51 to an arbitrary position on frame portion 21. One or more suction nozzles 53 are provided below mounting head 52. Mounting head 52 performs a mounting operation of picking up the component from a component supply position of tape feeder 45 using suction nozzle 53 and mounting the component on a board. Suction nozzle 53 is one form of a component mounting tool that collects a component from reel 46. As the component mounting tool, a chuck type mounting tool that sandwiches the component may be used.

Nozzle station 55 is provided adjacent to component supply unit 4. Nozzle station 55 is provided with replaceable nozzle tray 56 in which multiple suction nozzles 53 are replaceably accommodated. In nozzle station 55, exchange between suction nozzle 53 attached to mounting head 52 and suction nozzle 53 accommodated in nozzle tray 56 is performed as necessary.

Part camera 58 is provided upward between board conveyance device 3 and component supply unit 4. Part camera 58 captures an image of the component held by suction nozzle 53 from below to acquire image data while mounting head 52 moves from component supply unit 4 to the board. By performing image processing on the image data, the position and posture of the component with respect to suction nozzle 53 are detected and reflected in the mounting operation. As part camera 58, a digital imaging device having an imaging element such as CCD or CMOS can be exemplified.

Control device 6 includes a computer device having CPU and operated with software. The attachment position of control device 6 is not limited. Control device 6 may be configured such that multiple CPUs are distributed and disposed inside the device and are connected in communication with each other. Control device 6 controls the mounting operation based on mounting data PD stored in a memory (not illustrated). In other words, control device 6 controls board conveyance device 3, component supply unit 4, head moving device 5, and the like based on mounting data PD. Mounting data PD is created for each type of board. Mounting data PD includes design data, component data, and arrangement data.

The design data describes the type of the board, the type, the number, and the mounting position of the component to be mounted on the board, and the like. The component data describes the external dimensions and external color of the component, the arrangement and dimensions of the electrodes provided on the component, the type (handling method) of suction nozzle 53 used to pick up the component, and the like. The arrangement data describes a coordinate value of a component supply position of each of multiple tape feeders 45, a type of a component supplied by each of multiple tape feeders 45, and the like.

Control device 6 creates machine log data LD representing the history of the mounting operation. Normally, every time the mounting operation ends, control device 6 creates machine log data LD related to the mounting operation and stores machine log data LD in a memory (not illustrated). Further, control device 6 transmits machine log data LD to line management device 95 described later substantially in real time. Machine log data LD may also represent an operation history other than the mounting operation, for example, a conveyance history of the board or an exchange history of suction nozzle 53. Machine log data LD will be described in detail later.

In component mounter 1, an error in which the mounting operation fails occurs once in a while. Examples of the error in the mounting operation include the following cases 1) to 7).
1) A case where image data is not acquired by part camera 58.
2) A case where image data is not subjected to appropriate image processing.
3) A case where it is determined that suction nozzle 53 does not pick up a component as a result of the image processing.
4) A case where it is determined that the type of the component is wrong, as a result of the image processing.
5) A case where an error in a posture of a component is large as a result of the image processing and it is determined that mounting operation is impossible.

6) A case where the component falls from suction nozzle 53 while mounting head 52 moves from part camera 58 to the board.
7) A case where the component is not mounted on the board while being picked up by suction nozzle 53.

The location of the cause of the error varies such as a device such as tape feeder 45 or suction nozzle 53, reel 46, and mounting data PD.

Here, when the location of the cause is reel 46, the following factors A) to C) are considered.
A) Quality of reel 46: an increase in the feed load of the carrier tape due to a defective shape or a defective support posture of reel 46, a positional deviation of the feed hole of the carrier tape, a positional deviation of the cavity, an error or variation in the inner dimension of the cavity, an unstable peeling state of the cover tape, and the like.
B) Size of component accommodated in cavity: an error in the external dimension of the component (the positive error is large even within the tolerance, or the negative error is large even within the tolerance), a variation in the external dimension of the component (positive or negative variation within the tolerance), and the like.
C) Exchange operation of reel 46: defect in splicing work of connecting two carrier tapes, defect in loading work of loading a new carrier tape, defect in setting work of a new reel, and the like. The occurrence of an error due to this factor is rare and is irrelevant to the quality of reel 46, and even if an error occurs, the operator takes measures to correct the error, so that there is no need to regard it as a serious issue.

According to an empirical rule, the factors A) and B) described above do not occur randomly, but often occur frequently in some of reels 46. For example, errors in the mounting operation caused by reel 46 frequently occur in a specific vendor of a component, in a specific type of a component, or in a specific lot of a component. Therefore, it is possible to contribute to examination and implementation of an effective countermeasure by a processing method in which reels 46 are grouped by vendor, type, or lot of the component and error information (history of error occurrence status) is aggregated or statistically processed. Production management device 7 of the embodiment adopts this processing method. This processing method applies “stratification” of the QC seven tools.

### 2. Functional Configuration of Production Management Device 7 of Embodiment

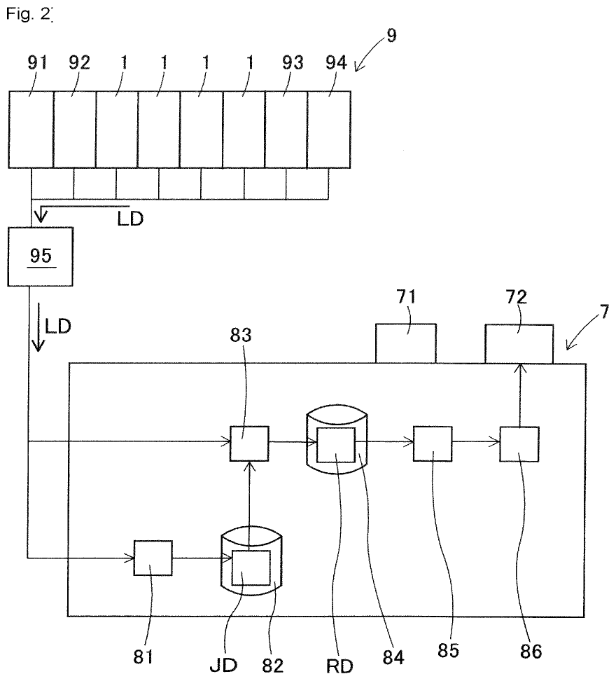

Next, a functional configuration of production management device 7 of the embodiment will be described with reference to FIG. 2. Production management device 7 is applied to four component mounters 1 constituting board production line 9. To four component mounters 1, machine ID information for identifying the respective component mounters are assigned; for example, M1 to M4. Board production line 9 includes eight board production work machines arranged side by side. Specifically, board production line 9 includes solder printing machine 91, printing inspection machine 92, four component mounters 1, board visual inspector 93, and reflow machine 94 arranged side by side. Furthermore, line management device 95 that manages the operation status of the eight board production work machines is provided. The line configuration of board production line 9 can be variously changed. Further, production management device 7 may be applied to component mounters 1 disposed in multiple board production lines 9.

Line management device 95 receives machine log data LD from each of the board production work machines in substantially real time. The data format of machine log data LD may be different for each type of board production work machine, or may be unified. Line management device 95 transmits machine log data LD received from control device 6 of at least four component mounters 1 to production management device 7. This transmission may be performed substantially in real time, may be performed when multiple pieces of machine log data LD are accumulated, or may be performed according to a transmission request from production management device 7. Control device 6 of component mounter 1 may directly transmit machine log data LD to production management device 7.

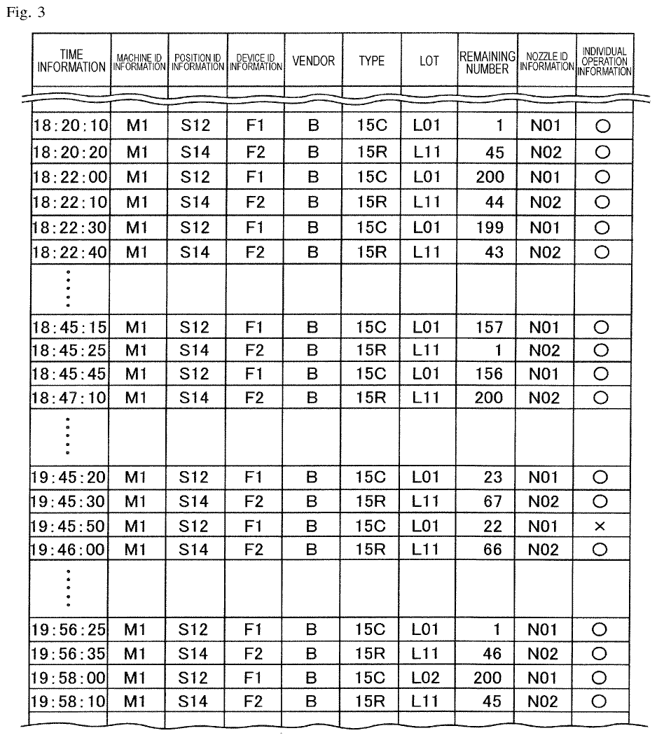

FIG. 3 illustrates an example of machine log data LD of component mounter 1 whose machine ID information is M1. Each row in FIG. 3 corresponds to one machine log data LD. Machine log data LD has a data format in which ten pieces of information are associated. That is, machine log data LD is associated with time information, machine ID information, position ID information, device ID information, vendor, type, lot, remaining number, nozzle ID information, and individual operation information. Since machine log data LD is generally handled in time series, machine log data LD of four component mounters 1 is actually mixed.

The time information represents a time (hour, minute, second) at which the mounting operation is performed, and is represented by, for example, a timing at which the lifting of suction nozzle 53 mounting the component on the board ends. The machine ID information is information for identifying each of four component mounters 1 as described above. The position ID information is information for identifying each of multiple slots 42 as described above. The device ID information is information for identifying each of multiple tape feeders 45 as described above.

The information of the vendor, the type, and the lot is information indicating the vendor, the type, and the lot of the component accommodated in reel 46. The remaining number information is information indicating the number of components remaining on reel 46 at the start or end of the mounting operation. The nozzle ID information is information for identifying each of suction nozzles 53 used in the mounting operation. The individual operation information is information indicating whether an error has occurred in the mounting operation. In FIG. 3, a normal end of the mounting operation is indicated by an O mark, and occurrence of an error is indicated by an X mark.

Returning to FIG. 2, production management device 7 is configured using a computer device. Production management device 7 includes input device 71 such as a keyboard or a touch panel that receives a command, a selection operation, or the like from an operator or the like. Further, production management device 7 includes display device 72 such as a liquid crystal display that displays various information to the operator or the like. Production management device 7 includes determination section 81, determination database 82, storage section 83, reel database 84, aggregation section 85, and display section 86.

When the individual operation information of machine log data LD includes an X mark (error occurrence), determination section 81 performs the determination processing after waiting for the end of use of reel 46 used for the mounting operation. Determination section 81 determines the location of the cause of the mounting operation error. There are four candidates for the location of the cause: tape feeder 45, suction nozzle 53, reel 46, and mounting data PD. Determination section 81 may determine whether the location of the cause is reel 46 as a minimum function. Determination section 81 stores determination data JD representing the result of the determination processing in determination database 82. The applicant of the present application discloses, in Japanese U.S. Pat. No. 7,142,149, a “mounting error cause estimation device” corresponding to a configuration example of determination section 81.

In summary of the above patent, the cause estimation device selects two candidates of the location of the cause, and determines whether each candidate is the location of the cause according to an error occurrence status when a first candidate is fixed and a second candidate is changed. For example, the cause estimation device first selects suction nozzle 53 and reel 46 as candidates for the location of the cause, and fixes suction nozzle 53. Next, when an error occurs in multiple reels 46 that have been used so far in combination with suction nozzle 53, the cause estimation device estimates that suction nozzle 53 is the location of the cause. In addition, when an error occurs only in specific reel 46 among multiple reels 46, the cause estimation device estimates that suction nozzle 53 is not the location of the cause but specific reel 46 is the location of the cause. Further, the cause estimation device can improve the estimation accuracy by performing estimation in which the combination of the two candidates is changed.

Storage section 83 stores sorting information for sorting reels 46 into multiple groups and error information in component mounter 1 in association with identification information of each of multiple reels 46. Specifically, storage section 83 creates reel data RD in which multiple types of sorting information belonging to each of multiple types of sorting criteria and different from each other and error information are associated with each of the identification information of multiple reels 46, and stores reel data RD in reel database 84. As will be described later, storage section 83 determines the use end time of reel 46 from machine log data LD, and creates and stores reel data RD for each reel 46 whose use has ended.

Multiple types of sorting criteria described above include a vendor, a type, and a lot of a component accommodated in reel 46. Therefore, specific proper nouns of the multiple vendors correspond to the multiple pieces of sorting information belonging to the sorting criterion of the vendor. The sorting information belonging to the sorting criterion of the type corresponds to a specific type name of the component, a symbol indicating the type, or the like. Further, the sorting information belonging to the sorting criterion of the lot corresponds to a specific lot name of the lot, a symbol indicating the lot, and the like.

The error information is information indicating an error occurrence history of the mounting operation in component mounter 1. In the embodiment, the error information is represented using multiple error ranks in which the quality of the error occurrence status is ranked. Further, the error rank is represented using the number of occurrences of errors for each reel 46. For example, the error rank is represented using two ranks of “error presence” in which the number of occurrences of errors for each reel 46 is one or more and “error absence” in which the number of occurrences of errors is zero. Without being limited thereto, three or more error ranks may be used. For example, four error ranks such as ranks in which the number of occurrences of errors for each reel 46 is 0, 1, 2-3, and 4 or more may be used. The error information may be represented by an indicator other than the error rank based on the number of occurrences of errors, for example, an error occurrence rate for each reel 46.

The identification information of reel 46 is represented by, for example, reel ID information assigned to each reel 46. Specifically, a barcode including reel ID information is attached to each of reels 46, and the operator uses a barcode reader to read the barcode. Thus, control device 6 can acquire the reel ID information. In general, the barcode includes component specifying information indicating the vendor, the type, the lot, the accommodation number, and the like of the component in addition to the reel ID information. Alternatively, the barcode can be associated with component specifying information stored in advance in a component database (not illustrated).

In the embodiment, a case where the reel ID information is not used is considered. That is, instead of the reel ID information, storage section 83 sets a combination of the use period of reel 46, the machine ID information, and the device ID information or the position ID information as the identification information of reel 46. That is, storage section 83 identifies individual reel 46 by specifying the time and position of use of reel 46. This identification method is also used in determination section 81 and aggregation section 85. One of the device ID information and the position ID information can specify the position where reel 46 is used, and thus it is not necessary to combine both.

Storage section 83 obtains the sorting information and the error information of each of multiple reels 46 from machine log data LD, and stores the information in association with the identification information of reel 46. Specifically, storage section 83 uses each piece of information of the vendor, the type, and the lot included in the acquired machine log data LD as the sorting information as it is. Further, storage section 83 obtains the use period of reel 46 based on the remaining number information included in machine log data LD. Then, storage section 83 combines the machine ID information, the device ID information or the position ID information, and the use period included in machine log data LD to obtain the identification information of reel 46. Further, storage section 83 obtains error information based on whether there is an X mark (error occurrence) in the individual operation information of multiple pieces of machine log data LD in the use period.

However, storage section 83 excludes an error in which the location of the cause is other than reel 46 from the error information. Specifically, storage section 83 acquires determination data JD from determination database 82, and sets the error information as the error presence when the location of the cause of the error (X mark of the individual operation information) is reel 46. When the location of the cause of the error is other than reel 46, storage section 83 sets the error information as the error absence. By setting only the error caused by reel 46 as the aggregation target, it is possible to make the aggregation result of aggregation section 85 easy to see and efficiently contribute to the examination of an effective countermeasure. If all errors are the aggregation targets, the error information includes not only errors caused by reel 46 but also errors caused by the device and mounting data PD. Therefore, the influence of many types of locations of causes is included in the aggregation result of aggregation section 85, and the examination of the countermeasure becomes inefficient.

aggregation section 85 aggregates or statistically processes the error information for each of multiple groups sorted by the sorting information for reel 46 used in a predetermined aggregation period. Specifically, aggregation section 85 acquires reel data RD from reel database 84, and aggregates or statistically processes the error information for each of multiple groups sorted by the sorting information belonging to the designated sorting criterion among the multiple types of sorting criteria. The designated sorting criterion may be designated every time by the operator, or may be set in advance. For example, when the designated sorting criterion is a vendor, aggregation section 85 aggregates or statistically processes the error information for each of multiple vendors.

In addition, aggregation section 85 may perform hierarchical or complex aggregation or statistical processing for groups sorted by multiple types of sorting information belonging to each of multiple types of designated sorting criteria. In an example of the hierarchical aggregation, aggregation section 85 can aggregate the error information for each of multiple vendors (aggregation of the first layer), and further aggregate the error information for each of multiple types or for each of multiple lots for a designated specific vendor (aggregation of the second layer).

In the embodiment, aggregation section 85 aggregates the number of reels 46 used in the aggregation period (hereinafter, referred to as usage number Nu) for each of the multiple groups. In addition, aggregation section 85 aggregates the number of reels 46 corresponding to at least one of the multiple error ranks in which the quality of the error information is ranked. When the error rank is represented by two ranks of error presence and error absence, aggregation section 85 aggregates the number of reels 46 corresponding to error presence or error absence.

Without being limited to the above, when three or more error ranks are used, aggregation section 85 may aggregate the number of reels 46 corresponding to each error rank. In addition, aggregation section 85 may obtain a ratio of reel 46 corresponding to each error rank to usage number Nu. When the error information is represented by an error occurrence rate, aggregation section 85 may obtain an average value (average error occurrence rate) of the error occurrence rates of multiple reels 46 for each of the multiple groups (an example of statistical processing).

The aggregation period in which aggregation is performed is set to be manually variable or set to a certain period in advance. For example, the operator may set an arbitrary aggregation period using input device 71. Further, in board production line 9 operating for 24 hours, a certain time (6 hours, 24 hours, or the like) may be set in advance as the aggregation period, and aggregation section 85 may automatically operate. Further, in board production line 9 in which the operation is stopped at night, the operation time in the daytime may be set as the aggregation period, and aggregation section 85 may automatically operate after the operation is stopped. In addition, in one board production line 9, a predetermined aggregation period may be set in advance in a busy period in which board production line 9 is operated for 24 hours, and an operation period in the daytime may be set as the aggregation period in a period in which board production line 9 is intermittently operated in a period other than the busy period. Further, in addition to the automatic setting of the aggregation period of a certain period, an arbitrary aggregation period may be manually set.

display section 86 displays the result of the aggregation or statistical processing of the error information by aggregation section 85 as a graph on display device 72. The aggregation result of aggregation section 85 is expressed by numerical information inside production management device 7. Even when the numerical information is displayed in a table format, it is difficult for an operator, a manager, and a designer to understand the numerical information. Therefore, display section 86 converts the aggregation result into a bar graph, a band graph, a line graph, or the like, and visualizes and displays the aggregation result so as to be easily seen by a person. The functions of determination section 81, storage section 83, aggregation section 85, and display section 86 will be further described in the following operation description.

### 3. Operation of Production Management Device 7

Next, the operation of production management device 7 will be described with reference to FIGS. 3 to 9. When exchanging reel 46 that has run out of components in component mounter 1 with new reel 46, the operator uses a barcode reader to read the barcode of new reel 46. Accordingly, control device 6 can acquire the component specifying information indicating the vendor, the type, the lot, the accommodation number, and the like of the component. In order to simplify the following description, it is assumed that the number of components accommodated in new reel 46 is 200. It should be noted that the actual accommodation number is much larger than 200.

In addition, it is assumed that component mounter 1 having the device ID information of M1 uses tape feeder 45 having the machine ID information of F1 which is provided in slot 42 having the position ID information of S12 and tape feeder 45 having the device ID information of F2 which is provided in slot 42 having the position ID information of S14. FIG. 3 illustrates machine log data LD of component mounter 1 having the machine ID information of M1. Actually, component mounter 1 generally uses more than two tape feeders 45. The actual time required for the mounting operation is shorter than that illustrated in FIG. 3.

In machine log data LD of which the time information is 18:20:10 in FIG. 3, tape feeder 45 of which the device ID information is F1 supplies a component of which the vendor is B, the type is 15C, and the lot is L01, and the remaining number is 1. For this component, the mounting operation was performed using suction nozzle 53 having the nozzle ID information of N01, and the individual operation information was the O mark (normal end). In addition, in machine log data LD of which the time information is 18:20:20, tape feeder 45 of which the device ID information is F2 supplies a component of which the vendor is B, the type is 15R, and the lot is L11, and the remaining number is 45. For this component, the mounting operation was performed using suction nozzle 53 having the nozzle ID information of N02, and the individual operation information was the O mark (normal end).

Further, in machine log data LD of which the time information is 18:22:00, tape feeder 45 of which the device ID information is F1 supplies a component of which the vendor is B, the type is 15C, and the lot is L01, and the remaining number is 200. Therefore, storage section 83 can recognize that first reel 46 has been exchanged with second reel 46 based on the change in the remaining number information. Storage section 83 stores the end time of the use period of first reel 46 as 18:20 (rounded down to seconds), and stores the start time of the use period of second reel 46 as 18:22.

In addition, in machine log data LD of which the time information is 19:56:25, tape feeder 45 of which the device ID information is F1 supplies a component of which the vendor is B, the type is 15C, and the lot is L01, and the remaining number is 1. Therefore, storage section 83 stores the end time of the use period of second reel 46 as 19:56. Further, similarly to second reel 46, storage section 83 stores the start time of the use period of third reel 46 as 19:58 based on machine log data LD having the time information of 19:58:00.

Further, in machine log data LD of which the time information is 19:45:50, tape feeder 45 of which the device ID information is F1 supplies the component of which the vendor is B, the type is 15C, and the lot is L01, and the individual operation information is the X mark (error occurrence). At this time, determination section 81 has not yet performed the determination processing, and the location of the cause of the error is unknown.

In order to simplify the following description, it is assumed that component mounter 1 having the machine ID information of M2 uses tape feeder 45 having the device ID information of F3 provided in slot 42 having the position ID information of S08 and tape feeder 45 having the device ID information of F4 provided in slot 42 having the position ID information of S11. It is assumed that component mounter 1 having the machine ID information of M3 uses tape feeder 45 having the device ID information of F5 mounted in slot 42 having the position ID information of S10 and tape feeder 45 having the device ID information of F6 mounted in slot 42 having the position ID information of S13. It is assumed that component mounter 1 having the machine ID information of M4 uses tape feeder 45 having the device ID information of F7 mounted in slot 42 having the position ID information of S09.

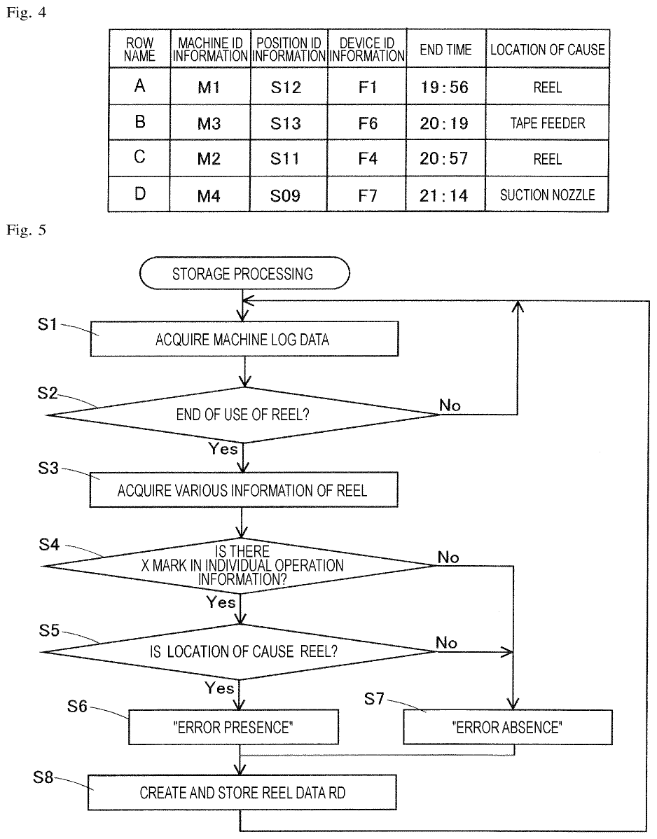

Determination section 81 performs the determination processing after waiting for the end of the use of reel 46 used for the mounting operation for the X mark (error occurrence) included in machine log data LD of four component mounters 1 having the machine ID information of M1 to M4. Determination section 81 stores determination data JD created in the determination processing in determination database 82. As illustrated in FIG. 4, in determination data JD, the machine ID information, the position ID information, the device ID information, the end time of the use period of reel 46, and the location of the cause are associated with each other. The row names A to D are added for convenience in order to distinguish four determination data JD. As described above, the combination of the machine ID information, the position ID information, the device ID information, and the information of the end time corresponds to the identification information of reel 46. Instead of the information of the end time, information of the start time of the use period may be used.

From the identification information of reel 46 (combination of the machine ID information, the position ID information, the device ID information, and the information of the end time), it can be seen that determination data JD in the row A is determined for the X mark of machine log data LD having the time information of 19:45:50 in FIG. 3. Determination data JD in the row A indicates that the location of the cause of the error is reel 46. In addition, determination data JD in the row B indicates that the location of the cause of the error occurring in component mounter 1 of which the machine ID information is M3 is tape feeder 45. Determination data JD in the row C indicates that the location of the cause of the error occurring in component mounter 1 having the machine ID information of M2 is reel 46. Determination data JD in the row D indicates that the location of the cause of the error occurring in component mounter 1 having the machine ID information of M4 is suction nozzle 53.

Storage section 83 continuously executes the storage processing illustrated in FIG. 5. In Step S1 of FIG. 5, storage section 83 acquires machine log data LD of component mounter 1. In next Step S2, storage section 83 determines whether the remaining number information included in acquired machine log data LD is 1, in other words, whether it is the use end time of reel 46. Storage section 83 returns the processing flow to Step S1 when it is not the use end time, and advances the processing flow to Step S3 when it is the use end time.

In Step S3, storage section 83 acquires various information for reel 46 whose use end time has come. Specifically, storage section 83 first acquires all information included in machine log data LD. Next, storage section 83 sets the time information included in machine log data LD as the end time of the use period of reel 46. Next, storage section 83 retroactively searches for machine log data LD in which the machine ID information, the position ID information, and the device ID information match, and sets the time information of machine log data LD in which the remaining number information is 200 as the start time of the use period of reel 46. Thus, the identification information of reel 46 is confirmed. Each piece of information of the vendor, the type, and the lot included in machine log data LD becomes the sorting information as it is.

Next, in Step S4, storage section 83 determines whether the machine ID information, the position ID information, and the device ID information match each other, and whether there is the X mark (error occurrence) in the individual operation information of all machine log data LD included in the use period (from the start time to the end time). Storage section 83 advances the processing flow to Step S5 when there is the X mark, and branches the processing flow to Step S7 when there is no X mark. In Step S5, storage section 83 acquires determination data JD from determination database 82 and determines whether the location of the cause of the error is reel 46. Storage section 83 advances the processing flow to Step S6 when the location of the cause is reel 46, and branches the processing flow to Step S7 when the location of the cause is not reel 46.

In Step S6, storage section 83 sets the error information as the error presence. In Step S7, storage section 83 sets the error information as the error absence. After the execution of Step S6 or Step S7, the processing flow joins Step S8. In Step S8, storage section 83 creates reel data RD corresponding to reel 46 and stores reel data RD in reel database 84.

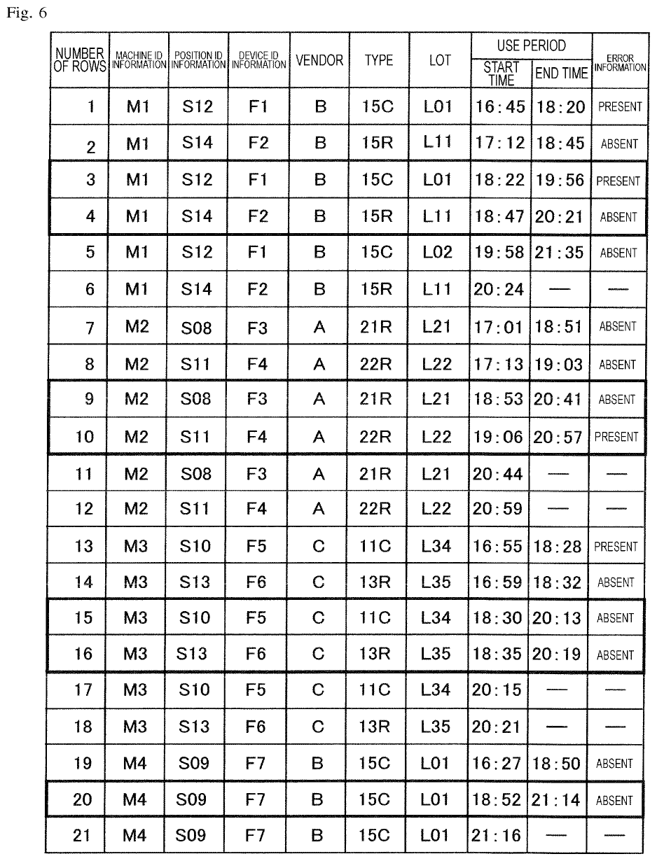

An example of reel data RD is illustrated in FIG. 6. Each row in FIG. 6 corresponds to one piece of reel data RD and corresponds to one reel 46. Reel data RD has a data format in which nine pieces of information are associated. That is, reel data RD is associated with the machine ID information, position ID information, device ID information, vendor, type, lot, start time and end time of the use period, and error information. In the column of the error information, “error presence” is abbreviated as “present”, and “error absence” is abbreviated as “absent”. In addition, the number of rows 1 to 21 is added for convenience in order to distinguish the multiple pieces of reel data RD.

Here, a specific example of the storage processing of storage section 83 will be described for second reel 46 in which the individual operation information is marked with X in machine log data LD with the time information of 19:45:50 in FIG. 3. In Step S1, storage section 83 acquires machine log data LD whose time information is 19:56:25. Then, since the remaining number information included in machine log data LD is 1, storage section 83 acquires all the information included in machine log data LD in Step S3. That is, storage section 83 acquires the time information of 19:56:25, the machine ID information of M1, the position ID information of S12, the device ID information of F1, the vendor of B, the type of 15C, the lot of L01, the remaining number of 1, the nozzle ID information of N01, and the individual operation information of the O mark.

Next, storage section 83 sets 19:56, which is the time information included in machine log data LD, as the end time of the use period of second reel 46. Next, storage section 83 retroactively searches for machine log data LD in which the machine ID information is M1, the position ID information is S12, and the device ID information is F1. As a result of the retrospective search, storage section 83 sets 18:22, which is the time information included in machine log data LD in which the remaining number information is 200, as the start time of the use period of second reel 46. Further, storage section 83 sets the acquired information of the vendor of B, the type of 15C, and the lot of L01 as the sorting information as it is.

Further, in Step S4, storage section 83 searches for all machine log data LD in which the machine ID information is M1, the position ID information is S12, and the device ID information is F1 and which is included in the use period (18:22 to 19:56), and confirms the individual operation information. As a result, storage section 83 recognizes that the individual operation information included in machine log data LD whose time information is 19:45:50 is the X mark. Then, in Step S5, storage section 83 determines that the location of the cause of the error is reel 46 based on determination data JD of the row A, and in Step S6, storage section 83 sets the error information as the error presence. Storage section 83 finally creates reel data RD illustrated in the third row of FIG. 6 and stores reel data RD in reel database 84.

In FIG. 6, reel data RD corresponding to first reel 46 used before second reel 46 is illustrated in the first row, and reel data RD corresponding to third reel 46 used after second reel 46 is illustrated in the fifth row. Moreover, reel data RD corresponding to reel 46 used in the tape feeder having the device ID information of F2 installed in component mounter 1 having the machine ID information of M1 is illustrated in the second row, the fourth row, and the sixth row. Reel data RD corresponding to reels 46 used in three component mounters 1 having the machine ID information of M2 to M4 are illustrated in the seventh to twenty-first rows.

With respect to reel data RD of the tenth row, storage section 83 recognizes that the individual operation information included in machine log data LD of the use period has the X mark. Then, storage section 83 determines that the location of the cause of the error is reel 46 based on determination data JD of the row C, and sets the error information of reel data RD of the tenth row as the error presence. With respect to reel data RD of the sixteenth row, storage section 83 recognizes that the individual operation information included in machine log data LD of the use period has the X mark. Even so, storage section 83 determines that the location of the cause of the error is not reel 46 based on determination data JD of the row B, and sets the error information of reel data RD of the sixteenth row as the error absence without considering (excluding) the X mark. With respect to reel data RD of the twentieth row, storage section 83 recognizes that the individual operation information included in machine log data LD of the use period has the X mark. However, storage section 83 determines that the location of the cause of the error is not reel 46 based on determination data JD in the row D, and sets the error information of reel data RD in the twentieth row as the error absence without considering (excluding) the X mark.

Reel data RD of the sixth row, the eleventh row, the twelfth row, the seventeenth row, the eighteenth row, and the twenty-first row is unconfirmed data in which the end time and the error information are not determined, and indicates that reel 46 is still in use. These pieces of unconfirmed data need not be stored in reel database 84 at the present time. The end time and the error information of the unconfirmed data are confirmed and stored after the use of reel 46 ends.

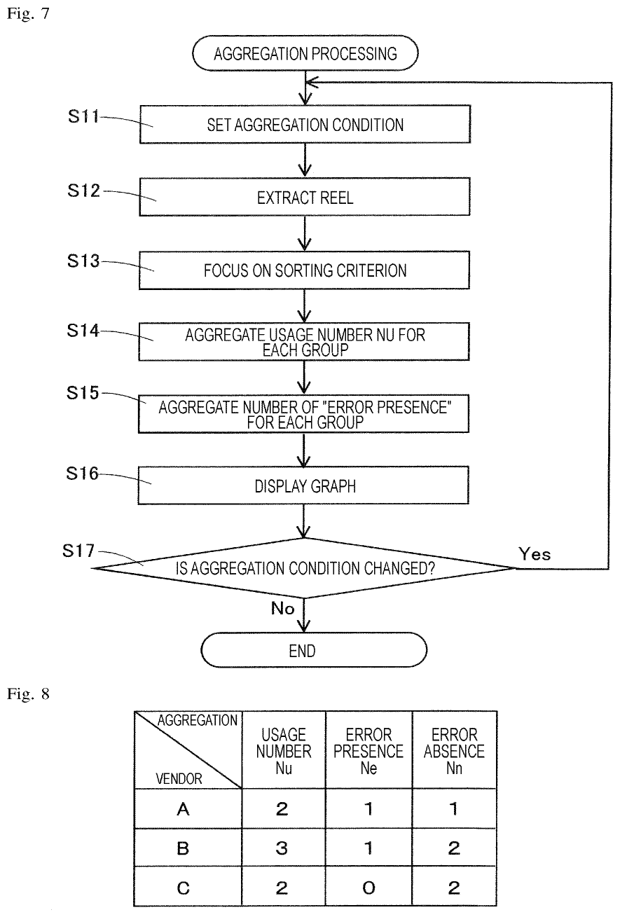

Aggregation section 85 executes the aggregation processing illustrated in FIG. 7. A part of the processing in FIG. 7 is executed by the operator and display section 86. In Step S11 of FIG. 7, the operator sets an aggregation period as an aggregation condition and designates a sorting criterion. The present disclosure is not limited thereto, and the aggregation condition may be automatically set in advance. In the next Step S12, aggregation section 85 extracts reel data RD corresponding to reel 46 used in the aggregation period. At this time, only reel 46 in which the entire use period falls within the aggregation period may be extracted, or reel 46 in which a part of the use period overlaps the aggregation period may be extracted together. However, reel 46 in use is excluded from the extraction target.

As an example, it is assumed that the current time is 21:40, an aggregation period from 18:00 to 21:30 is set, and a vendor is designated as a sorting criterion. Aggregation section 85 extracts seven pieces of reel data RD (indicated by being surrounded by a thick frame) of the third row, the fourth row, the ninth row, the tenth row, the fifteenth row, the sixteenth row, and the twentieth row in FIG. 6 in which the entire use period falls within the aggregation period. Alternatively, aggregation section 85 may also extract reel data RD in which a part of the use period overlaps the aggregation period. That is, aggregation section 85 may extract eight pieces of reel data RD of the first row, the second row, the fifth row, the seventh row, the eighth row, the thirteenth row, the fourteenth row, and the nineteenth row in addition to the seven pieces of reel data RD described above.

In the next Step S13, aggregation section 85 focuses on the set sorting criterion and focuses on the sorting information of each of the multiple pieces of extracted reel data RD. In the next Step S14, aggregation section 85 aggregates usage number Nu of reels 46 for each of the multiple groups sorted by the sorting information. That is, aggregation section 85 focuses on the vendor information included in the seven pieces of reel data RD described above, and aggregates usage number Nu of vendor A as 2 (see the ninth row and the tenth row). Further, similarly to the case of vendor A, aggregation section 85 aggregates usage number Nu of vendor B as 3 (see the third row, the fourth row, and the twentieth row), and aggregates usage number Nu of vendor C as 2 (see the fifteenth row and the sixteenth row). The aggregate value is illustrated in the column of usage number Nu in FIG. 8 representing the aggregation result.

In the next Step S15, aggregation section 85 aggregates the number of reels 46 corresponding to the error presence for each of the multiple groups. That is, aggregation section 85 aggregates number Ne corresponding to the error presence of vendor A as 1 (see the tenth row). Further, similarly to the case of vendor A, aggregation section 85 aggregates number Ne corresponding to the error presence of vendor B as 1 (see the third row), and aggregates number Ne corresponding to the error presence of vendor C as 0. Number Ne is illustrated in the column of error presence Ne in FIG. 8. Aggregation section 85 may aggregate number Nn of error absence illustrated in FIG. 8 instead of number Ne of the error presence, or may aggregate both number Ne of error presence and number Nn of error absence.

In the next Step S16, display section 86 converts the aggregation result of aggregation section 85 illustrated in FIG. 8 into a graph and displays the graph on display device 72. Display section 86 displays, for example, a bar graph for each vendor illustrated in FIG. 9. In this bar graph, three bars corresponding to vendor A, vendor B, and vendor C are illustrated. The length of each bar indicates an error ratio obtained by dividing the number Ne of error presence by usage number Nu in %. Further, display section 86 displays number Ne of the error presence and usage number Nu in a fractional format on the upper portion of each bar. The present disclosure is not limited thereto, and display section 86 may use another display format, and for example, may display the error ratio for each vendor in one pie chart.

In the next Step S17, the operator determines whether to change the aggregation condition. When the aggregation condition is changed, the processing flow returns to Step S11. As a result, the operator can change at least one of the aggregation period and the sorting criterion to execute re-aggregation and re-display. Alternatively, the operator can designate a specific vendor based on the aggregation result for each vendor, and execute aggregation (hierarchical aggregation) and display for each type of component or for each lot. When the aggregation condition is not changed, the processing flow ends.

### 4. Another Operation Example of Aggregation Section 85 and Display Section 86

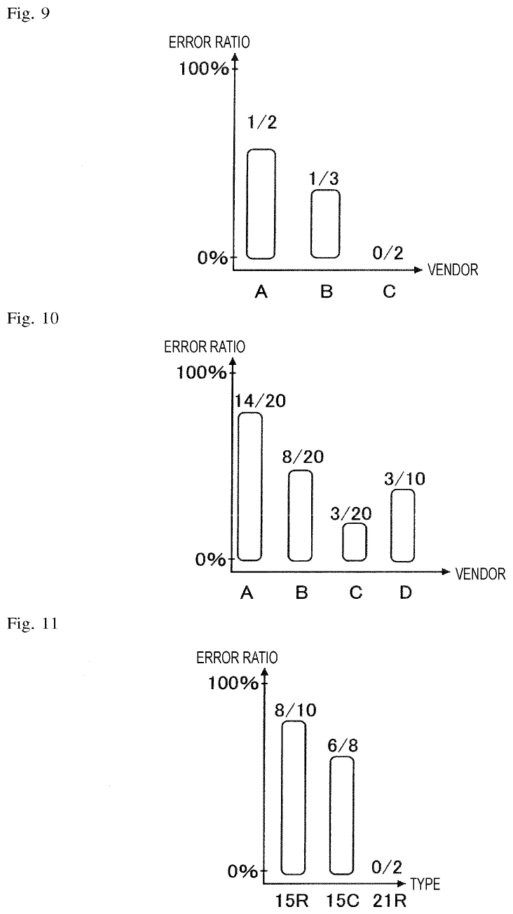

Next, another operation example of aggregation section 85 and display section 86 will be described with reference to FIGS. 10 to 13. Even when a longer aggregation period is set, aggregation section 85 can obtain a second aggregation result by executing the same aggregation processing as described above. Further, display section 86 can display the second aggregation result as illustrated in FIG. 10 using the same display format as in FIG. 9. In the bar graph illustrated in FIG. 10, four bars corresponding to vendors A to D are illustrated. Number Ne of the error presence and usage number Nu are displayed in a fractional format, and are 14/20 for vendor A, 8/20 for vendor B, 3/20 for vendor C, and 3/10 for vendor D.

The operator can designate, for example, vendor A having the largest error ratio, and execute aggregation and display for each type of component. Aggregation section 85 targets reel 46 of vendor A according to the designation of the operator, aggregates usage number Nu and number Ne of the error presence for each type, and obtains a third aggregation result. Display section 86 displays the third aggregation result as illustrated in FIG. 11 using the same display format as in FIGS. 9 and 10. In the bar graph illustrated in FIG. 11, three bars corresponding to component types 15R, 15C, and 21R are illustrated. Further, number Ne of the error presence and usage number Nu are displayed in a fractional format, and are 8/10 for type 15R, 6/10 for type 15C, and 0/2 for type 21R.

Based on the second and third aggregation results, the manager or the designer recognizes that the error ratio of reel 46 of vendor A is larger than those of vendors B to D. Further, the manager or the designer recognizes that the error ratio is high in reel 46 that supplies the component of type 15R and the component of type 15C in vendor A, and no error occurs in reel 46 that supplies the component of type 21R. The manager or the designer can reflect the recognized matter in the effective countermeasure.

As a countermeasure, for example, vendor A may be requested to improve the quality of reel 46. In this case, it is possible to contribute to a specific improvement measure for quality improvement by presenting the aggregation result. As a countermeasure, the use of reel 46 of vendor A may be avoided. In this case, by referring to the aggregation result, it is possible to appropriately narrow down the range of reels 46 not to be used and limit the spreading range.

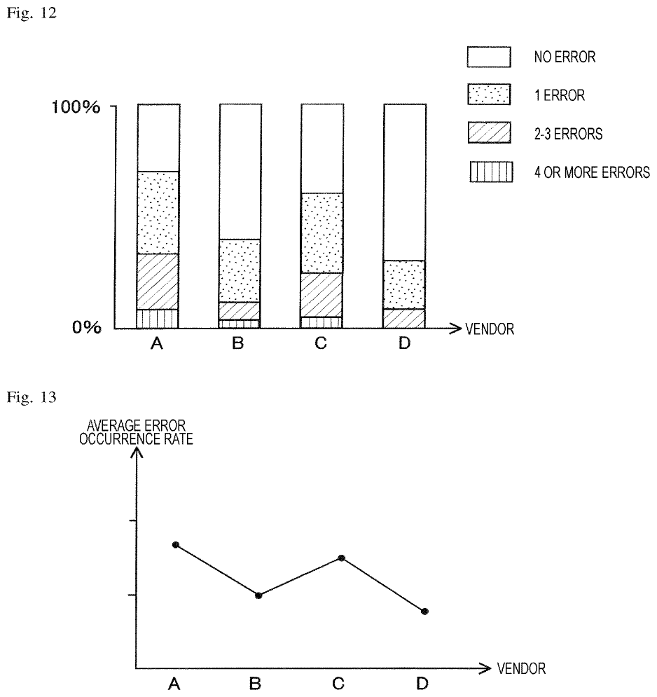

Aggregation section 85 can use a method other than the aggregation processing described in FIG. 7. For example, aggregation section 85 may aggregate the number of reels 46 corresponding to four error ranks for each vendor, and may obtain a ratio of reel 46 corresponding to each error rank to usage number Nu for each vendor as an aggregation result. Display section 86 can display the aggregation result of aggregation section 85 in the band graph illustrated in FIG. 12. In FIG. 12, for each of vendors A to D, the ratio of four error ranks in which the number of occurrences of errors is 0, 1, 2 to 3, and 4 or more is displayed in the band graph.

As described above, the error information may be represented by an error occurrence rate. In this case, aggregation section 85 can obtain an average value (average error occurrence rate) of the error occurrence rates of multiple reels 46 for each vendor and use the average value as an aggregation result. Display section 86 can display the aggregation result of aggregation section 85 on the line graph illustrated in FIG. 13. In FIG. 13, the average error occurrence rates of vendors A to D are plotted with black circles, and four black circles are connected with a polygonal line.

In production management device 7 of the embodiment, storage section 83 stores the sorting information for grouping multiple reels 46 and the error information indicating the occurrence history of the error in the mounting operation in association with the identification information of each of multiple reels 46. Aggregation section 85 aggregates or statistically processes the error information for each group for reel 46 used in a predetermined aggregation period. As described above, unlike the conventional art in which it is determined whether the location of the cause is reel 46, detailed aggregation or statistical processing for each group is performed for multiple reels 46, and thus it is possible to compare the occurrence status of errors between groups and reflect the comparison result in an effective countermeasure. Furthermore, the productivity of component mounter 1 is expected to be improved by implementing an effective countermeasure.

### 5. Modification of Production Management Device 7

Production management device 7 of the embodiment can be modified by omitting determination section 81 and determination database 82. In this modification, determination data JD does not exist. When there is an X mark in the individual operation information included in machine log data LD of the use period of reel 46, storage section 83 unconditionally sets the error information of reel data RD as the error presence. Further, as the sorting criterion, it is possible to designate a sorting criterion related to handling of reel 46 in addition to the sorting criterion (vendor, type, and lot of the component) for sorting reel 46 itself. Specifically, the device ID information of tape feeder 45, the combination of the machine ID information of component mounter 1 and the position ID information of slot 42, the nozzle ID information of suction nozzle 53, and the component data in mounting data PD can be designated as the sorting criterion.

When the sorting criterion related to the handling of reel 46 is designated, aggregation section 85 can obtain the aggregation result contributing to the estimation of the location of the cause. For example, in a case where the device ID information of tape feeder 45 is designated as the sorting criterion, aggregation section 85 obtains an aggregation result obtained by aggregating usage number Nu of reels 46 and number Ne of the error presence for each individual tape feeder 45. Therefore, the operator or the like can easily find tape feeder 45 in which an error is likely to occur.

In addition, for example, it is possible to designate a sorting criterion for sorting reel 46 itself and a sorting criterion related to handling of reel 46 in combination and cause aggregation section 85 to perform complex statistical processing. For example, it is considered that a case where the error occurrence rate is used as the error information and the vendor of the component and the nozzle ID information are designated as the sorting criterion. In this case, aggregation section 85 can perform multiple regression analysis using the error occurrence rate as a response variable and the vendor of the component and the nozzle ID information as explanatory variables. According to the multiple regression analysis, it is possible to quantitatively analyze how a difference in vendors and an individual difference of suction nozzle 53 are related to an error, and to contribute to examination of a countermeasure.

### 6. Application and Modification of Embodiment

The data formats of machine log data LD and reel data RD can be appropriately modified. Storage section 83 may receive the machine log data not only from component mounter 1 but also from board visual inspector 93 and recognize an error in the mounting operation. According to this, since the machine log data of board visual inspector 93 includes the information of the inspection result in which the mounting position and the mounting posture of the mounted component are determined to be normal or error, the error range targeted by production management device 7 is expanded. In addition, the embodiment can be applied or modified in various manners.

### REFERENCE SIGNS LIST

1: component mounter 4: component supply unit 42: slot 45: tape feeder 46: reel 53: suction nozzle 6: control device 7: production management device 81: determination section 82: determination database 83: storage section 84: reel database 85: aggregation section 86: display section 9: board production line 95: line management device PD: mounting data LD: machine log data JD: determination data RD: reel data

1. A production management device comprising:
a storage section configured to store sorting information for sorting component accommodation members into multiple groups, the component accommodation members accommodating components and being replaceably set in a component supply device constituting a component mounter, and error information indicating an occurrence history of an error in a mounting operation of collecting the components from the component accommodation members and mounting the components on a board in the component mounter, in association with identification information of each of multiple component accommodation members; and
an aggregation section configured to aggregate or statistically process the error information for each of the multiple groups for the component accommodation members used in a predetermined aggregation period.

2. The production management device according to claim 1,
wherein the storage section stores multiple types of the sorting information belonging to multiple types of sorting criteria and different from each other and the error information in association with the identification information of each of the multiple component accommodation members, and
the aggregation section aggregates or statistically processes the error information for each of the multiple groups sorted by the sorting information belonging to a designated sorting criterion.

3. The production management device according to claim 2,
wherein the aggregation section performs hierarchical or complex aggregation or statistical processing on the group sorted by the multiple types of sorting information belonging to the multiple designated types of sorting criteria.

4. The production management device according to claim 2, wherein the multiple types of sorting criteria include two or more of a vendor, a type, and a lot of the component accommodated in the component accommodation member.

5. The production management device according to claim 4, wherein the aggregation section aggregates or statistically processes the error information for each of multiple vendors, and further aggregates or statistically processes the error information for each of multiple types or for each of multiple lots for a specific vendor.

6. The production management device according to claim 1, comprising:
a determination section configured to determine whether a location of a cause of the error is the component accommodation member,
wherein the storage section excludes the error of which the location of the cause is other than the component accommodation member from the error information.

7. The production management device according to claim 1, wherein the aggregation section aggregates, for each of the multiple groups, the number of the component accommodation members used in the aggregation period and the number of the component accommodation members corresponding to at least one of multiple error ranks obtained by ranking quality of the error information.

8. The production management device according to claim 7, wherein the error rank is represented using the number of occurrences of the error for each component accommodation member.

9. The production management device according to claim 8, wherein the error rank is represented using “error presence” in which the number of occurrences of the error is one or more and “error absence” in which the number of occurrences of the error is zero for each component accommodation member.

10. The production management device according to claim 9, wherein the aggregation section aggregates, for each of the multiple groups, the number of the component accommodation members used in the aggregation period and the number of the component accommodation members corresponding to the “error presence” or the “error absence”.

11. The production management device according to claim 1, wherein the aggregation period is set to be manually variable or set to a certain period in advance.

12. The production management device according to claim 1, wherein the storage section acquires machine log data representing a history of the mounting operation in the component mounter, obtains the sorting information and the error information of each of the multiple component accommodation members from the machine log data, and stores the sorting information and the error information.

13. The production management device according to claim 12,
wherein the machine log data includes individual operation information indicating whether the error has occurred in an individual mounting operation for each of the components, time information of the mounting operation, and remaining number information of the components accommodated in the component accommodation member, and
the storage section obtains a use period of the component accommodation members based on the remaining number information of the components, and obtains the error information based on the individual operation information of the use period.

14. The production management device according to claim 13,
wherein the machine log data includes machine ID information allowing identification of the component mounter and device ID information allowing identification of the component supply device or position ID information allowing identification of a position of the component supply device in the component mounter, and
the storage section sets a combination of the use period, the machine ID information, and the device ID information or the position ID information as the identification information of the component accommodation member.

15. The production management device according to claim 1, comprising:
a display section configured to display a result of the aggregation section aggregating or statistically processing the error information in a graph.

16. The production management device according to claim 1, wherein a sorting criterion to which multiple pieces of sorting information belong is at least one of the component supply device in which the component accommodation member is set, a position of the component supply device in the component mounter, a component mounting tool configured to collect the component from the component accommodation member, and component data describing a shape or a handling method of the component.

17. The production management device according to claim 1, wherein the component accommodation member is a combination of a carrier tape accommodating the component in each of multiple cavities arranged in a row and a reel around which the carrier tape is wound, or a tray configured to accommodate the component in each of multiple accommodation portions arranged in a lattice shape.
